(19) United States
(12) Patent Application Publication
(10) Pub. No.: US 2012/0086433 A1
(43) Pub. Date: Apr. 12, 2012

(54) MEMS-BASED CURRENT SENSING APPARATUS

(75) Inventors: SHIH-HSIEN CHENG, Kaohsiung City (TW); WU-CHI HO, Hsinchu City (TW); CHENG-TING LIN, Taoyuan County (TW); YU-TING CHENG, Taipei County (TW); PEI-FANG LIANG, Hsinchu County (TW); YUNG-CHANG CHEN, Changhua County (TW)

(73) Assignee: Industrial Technology Research Institute, Hsinchu (TW)

(21) Appl. No.: 12/980,107

(22) Filed: Dec. 28, 2010

(30) Foreign Application Priority Data
Oct. 6, 2010 (TW) 099133961

(51) Int. Cl. G01R 15/18

(52) U.S. Cl. 324/117 R

(57) ABSTRACT

The invention discloses an MEMS-based current sensing apparatus including: a flexible substrate joined onto an conducting wire; a sensing unit formed of an MEMS structure and disposed on the flexible substrate, the sensing unit outputting a response to a electromagnetic field induced by a current flowing in the conducting wire; and a readout circuit disposed on the flexible substrate and coupled to the sensing unit, the readout circuit monitoring the response to the electromagnetic field and calculating the amount of the current flow.

### TECHNICAL FIELD

The present disclosure relates to a current sensing apparatus, and more particularly, to a micro-electro-mechanical system (MEMS) current sensing apparatus based on the Faraday's law of induction.

### TECHNICAL BACKGROUND

The usage of energy is generally represented in units of energy (Joule) or power (Watt). To measure the energy usage or dissipation in a circuit, the electrical voltage or current is detected in a variety of measuring or sensing devices and methods. In order to save the energy consumption or to diminish the energy waste, it is of value to combine the information of energy usage with the communication technology of presence, so as to provide energy users with the related information for energy management of more efficiency.

However, applicability of the traditional current sensors for measuring the energy usage of electricity have been limited, due to some demerits such as large size, external electric source needed, and incapability of applying to the electrical wires of multiple conductors. Some have proposed MEMS current sensors based on the law of Lorentz force to measure a flowing current according to the mechanical deviation by the current-induced electromagnetic field, leading the foregoing drawbacks to be alleviated; nevertheless, their performance can not satisfy potential requirements in the residence or the industry. Therefore, it is in need of a current sensor of compactness, non-contact, passiveness, and friendly utility for enabling a user to obtain sufficient information of energy usage to manage and thus save the energy.

### TECHNICAL SUMMARY

According to one aspect of the present disclosure, one embodiment provides an MEMS-based current sensing apparatus including: a flexible substrate joined onto an conducting wire; a sensing unit formed of an MEMS structure and disposed on the flexible substrate, the sensing unit outputting a response to a electromagnetic field induced by a current flowing in the conducting wire; and a readout circuit disposed on the flexible substrate and coupled to the sensing unit, the readout circuit monitoring the response to the electromagnetic field and calculating the amount of the current flow. Furthermore, the sensing unit may comprise a conductor coil having a material of magnetic permeability therein, and having its linewidth parallel with the conducting wire larger than its linewidth perpendicular to the conducting wire.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 is a schematic diagram showing the architecture of an MEMS current sensing apparatus according to an embodiment of the present disclosure.

FIG. 2 is a side-view diagram showing the architecture of an MEMS current sensing apparatus according to an embodiment of the present disclosure.

FIG. 3 is a schematic architecture of an MEMS current sensing apparatus with a C-shaped clamp according to another embodiment of the present disclosure.

### DESCRIPTION OF THE EXEMPLARY EMBODIMENTS

For further understanding and recognizing the fulfilled functions and structural characteristics of the disclosure, several exemplary embodiments cooperating with detailed description are presented as the following.

According to the Ampere's law, when an electrical current flowing in a long conducting line, a magnetic field is induced in the neighborhood of the conducting line. The intensity of the magnetic field Bᵣ at a distance of r from the conducting line is proportional to the current flow:

$${B}_{r} = \frac{{μ}_{0} I}{2 π r} ,$$

wherein μ₀ denotes magnetic constant, and I denotes the magnitude of the flowing current. With regards to a conducting coil adjacent to the conducting line, the Faraday's law of induction predicts an electromotive force (EMF) of the coil in volts as

$$E M F ( v ) = - \frac{d φ}{d t} = - \int \frac{d ( {Br}^{} \cdot {A}^{} )}{d t} ,$$

wherein φ denotes the magnetic flux in wabers, \vec{A} denotes the surface vector of the conducting coil, and the direction of the electromotive force is given by the Lenz's law. It can be derived from the above equation that proportion relationship of the electromotive force satisfies EMF(ν) ∞ φ ∞ \vec{BR}•\vec{A} ∞ I to be designed as a current sensor.

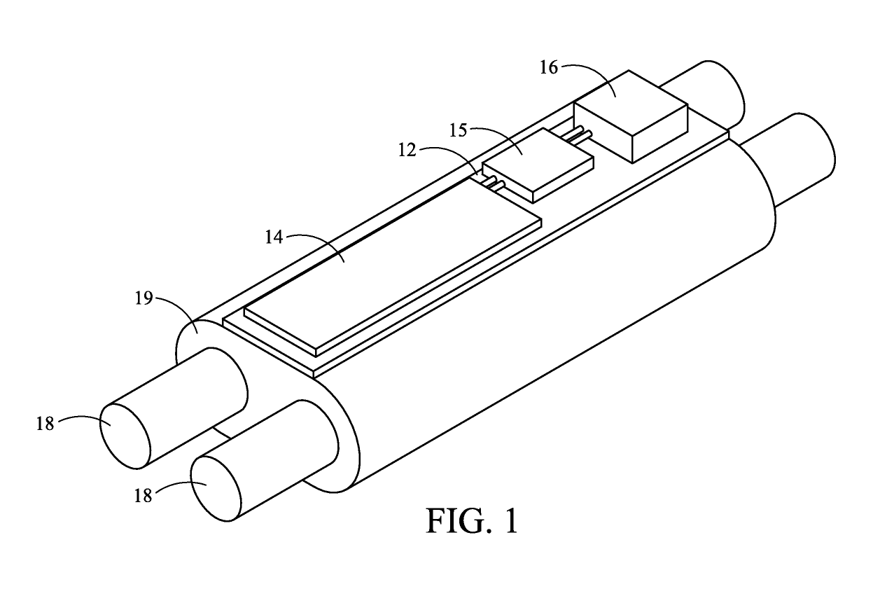

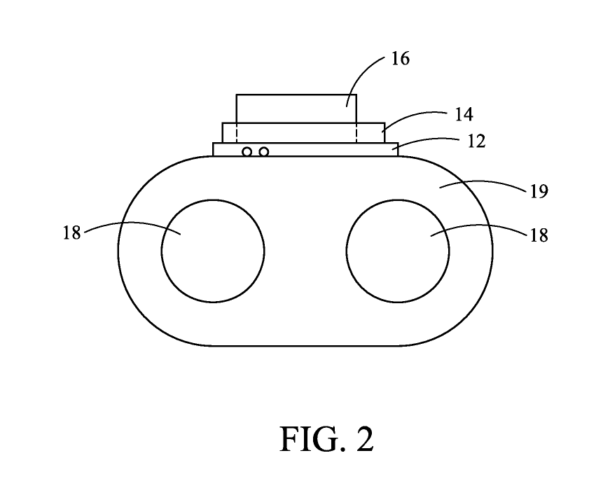

Please refer to FIGS. 1 and 2, which are schematic diagrams showing the architecture of an MEMS current sensing apparatus according to an embodiment of the present disclosure, FIG. 1 is its three-dimensional projective diagram and FIG. 2 is its corresponding side-view diagram. The embodiment includes: a flexible substrate 12, a sensing unit 14, an amplifier 15, and a readout circuit 16. Integration of all components of the embodiment can be designed and fabricated by the MEMS process, and flexibility of the flexible substrate 12 may facilitate convenience and achievability of a current sensor of compact size, non-contact, and passiveness.

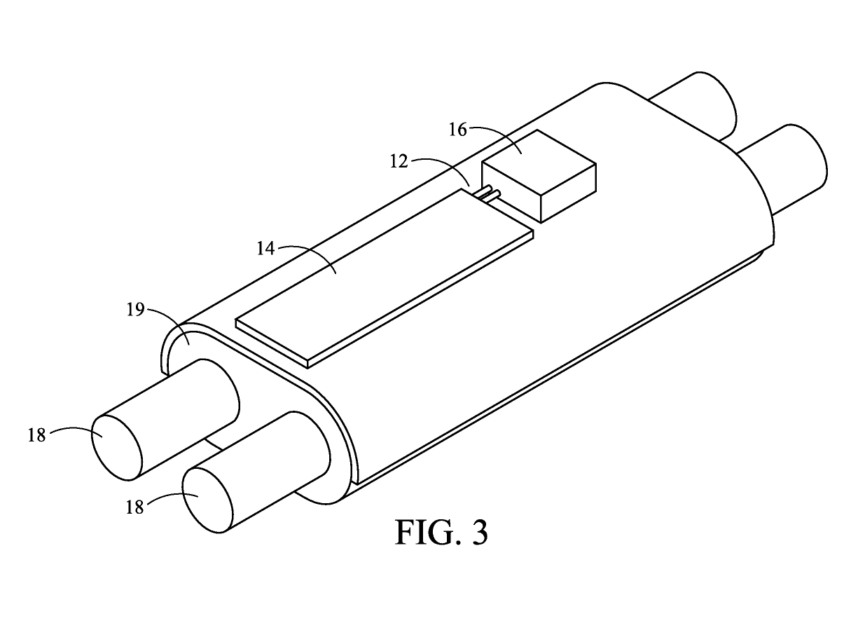

The lower surface of the flexible substrate 12 can be attached directly or indirectly onto a conducting wire 18 or a conductor covered in a protective jacket 19 of plastic, while the upper surface is used to dispose or form a sensing device and its circuit thereon. The flexible substrate 12 is formed of elastic material to attach to the conducting wire tightly; whereby the sensing unit 14 can get closer to the conducting wire 18 to gain a better effect of electromagnetic inductance. Due to the elastic and flexible features of the substrate 12, the current sensing apparatus of the embodiment is of convenience of “stick-and-play”, and is of tolerance to roughness and shapes of the conducting wire to be measured. Besides, the flexible substrate 12 may also be formed of C-shaped clamp, to clamp the protective jacket 19 of the conducting wire 18 directly, as shown in FIG. 3.

The sensing unit 14 is formed of an MEMS structure by the MEMS process and disposed on the flexible substrate 12, to measure the electromagnetic field induced by the current flowing in the conducting wire 18 and output a response corresponding to the electromagnetic field. The sensing unit 14 is composed of a conductor coil or a tightly-wound wire coil of at least one identical loop. For example, a copper coil with one loop is used as the sensing unit 14 in this embodiment, but is not limited thereby; it can be formed of another metal, or configured of coil of multiple loops to possibly increase the magnitude of electromagnetic induction. To further intensify the effect of magnetic permeability, a material of high magnetic permeability can be added in and covered in the conductor coil itself; moreover in an exemplary embodiment, the conductor coil may be patterned so that the linewidth parallel with the conducting wire 18 is larger than its linewidth perpendicular to the conducting wire 18.

The readout circuit 16 is disposed on the flexible substrate and coupled to the sensing unit 14 to monitor the response to the electromagnetic field induced by current flowing in the conducting wire 18 and calculating the amount of the current in the conducting wire 18. The readout circuit 16 may be fabricated by the process of complementary metal-oxide-semiconductor integrated circuits (CMOS-IC). The response from the sensing unit 14 may be of different form of energy parameter to be calculated or be too weak to be read by the readout circuit 16. Therefore, the amplifier 15 may be integrated into the readout circuit 16 to transduce or amplify the response of the sensing unit 14, but is not limited thereby; the amplifier 15 can be a discrete chip disposed on the flexible substrate 12 and coupled to the sensing unit and the readout circuit. In the embodiment, the amplifier 15 functions to transduce the response of current of the sensing unit 14 to a voltage or amplify the response of voltage to a current.

It should be noted, in this embodiment, the conductor coil is schemed according to the Faraday's law of induction and fabricated by the MEMS process to achieve compactness and integration of a passive current sensor. Another feature of the embodiment is the exploitation of the flexible substrate, so as to achieve a non-contact current sensor with ease to setup and use.

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. A micro-electro-mechanical system (MEMS) current sensing apparatus comprising:
a flexible substrate joined onto a conducting wire;
a sensing unit formed of an MEMS structure and disposed on the flexible substrate, the sensing unit outputting a response to a electromagnetic field induced by a current flowing in the conducting wire; and
a readout circuit disposed on the flexible substrate and coupled to the sensing unit, the readout circuit monitoring the response to the electromagnetic field and calculating the amount of the current.

2. The apparatus of claim 1, wherein the conducting wire is covered in a protective jacket of plastic.

3. The apparatus of claim 1, further comprising:
an amplifier coupled to the sensing unit and the readout circuit, the amplifier transducing or amplifying the response of the sensing unit.

4. The apparatus of claim 3, wherein the amplifier transduces the response of current to a voltage or amplifies the response of voltage to a current.

5. The apparatus of claim 1, wherein the flexible substrate is formed of elastic material to attach to the conducting wire tightly.

6. The apparatus of claim 1, wherein the sensing unit comprises a conductor coil.

7. The apparatus of claim 6, wherein the conductor coil is formed of metal.

8. The apparatus of claim 6, wherein the conductor coil has at least one turn .

9. The apparatus of claim 6, wherein the conductor coil comprises:
a material of magnetic permeability covered in the conductor coil itself.

10. The apparatus of claim 6, wherein the metal coil has its linewidth parallel with the conducting wire larger than its linewidth perpendicular to the conducting wire.

11. The apparatus of claim 1, wherein the readout circuit further comprises:
an amplifier transducing or amplifying the response of the sensing unit.

12. The apparatus of claim 1, wherein the readout circuit is formed by the process of complementary metal-oxide-semiconductor (CMOS) integrated circuits.
